(19) United States
(12) Patent Application Publication
(10) Pub. No.: US 2025/0246585 A1
(43) Pub. Date: Jul. 31, 2025

(54) SEMICONDUCTOR PACKAGE

(71) Applicant: Samsung Electronics Co., Ltd., Suwon-si (KR)

(72) Inventors: Daeyoung Jung, Suwon-si (KR); Jongbo Shim, Suwon-si (KR)

(21) Appl. No.: 18/886,044

(22) Filed: Sep. 16, 2024

(30) Foreign Application Priority Data
Jan. 26, 2024 (KR) 10-2024-0012459

(51) Int. Cl. H01L 25/16; H01L 23/00; H01L 23/31; H01L 23/498; H01L 25/18; H10B 80/00

(52) U.S. Cl. CPC H01L 25/162; H01L 23/3135; H01L 23/49811; H01L 23/49833; H01L 23/49838; H01L 24/32; H01L 25/18; H10B 80/00; H01L 24/16; H01L 24/73; H01L 2224/16148; H01L 2224/16227; H01L 2224/32225; H01L 2224/73204; H01L 2225/06513; H01L 2225/06517; H01L 2225/06541; H01L 2924/1433; H01L 2924/19041

(57) ABSTRACT

A semiconductor package includes a lower substrate with a first region and a second region surrounding the first region, and a lower interconnection layer; a first chip disposed at the first region and electrically connected to the lower interconnection layer; an upper substrate including an upper interconnection layer; connection structures disposed on the lower substrate in the second region and electrically connecting the lower substrate to the upper substrate; a second chip disposed on the upper substrate and electrically connected to the upper interconnection layer; a third chip disposed above the upper substrate and electrically connected to the upper interconnection layer; a molded portion disposed on the lower substrate and covering the first chip, a footprint of the molded portion being different than a footprint of the upper substrate with respect to a; and an auxiliary molded layer filling a space between the molded portion and the upper substrate.

### CROSS-REFERENCE TO RELATED APPLICATION(S)

This application claims the benefit under 35 USC 119(a) of Korean Patent Application No. 10-2024-0012459 filed on Jan. 26, 2024, in the Korean Intellectual Property Office, the entire disclosure of which is incorporated herein by reference for all purposes.

### BACKGROUND

The present inventive concept relates to semiconductor packages, and more particularly, to a semiconductor package having improved integration and reliability.

With the development of the electronics industry, demands for higher functionality, higher speed, and smaller electronic components are increasing. According to this trend, research into a system in package (SIP) requiring complexity and multifunctionality in terms of functionality is being undertaken. In terms of structure, a package-on-package (POP) structure is being developed in which multiple semiconductor chips are stacked and mounted on a package substrate or other semiconductor packages are stacked on a semiconductor package. In detail, research is being actively conducted to simultaneously secure miniaturization and reliability in such semiconductor packages.

### SUMMARY

Example embodiments provide a semiconductor package having improved integration and structural reliability.

According to example embodiments, a semiconductor package includes a lower substrate having an upper surface including a first region and a second region surrounding the first region, and the lower substrate including a lower interconnection layer; a first semiconductor chip disposed on the lower substrate in the first region and electrically connected to the lower interconnection layer; an upper substrate disposed above the lower substrate and spaced apart from the first semiconductor chip in a vertical direction, and the upper substrate including an upper interconnection layer; connection structures disposed on the lower substrate in the second region and electrically connecting the lower substrate to the upper substrate; a second semiconductor chip disposed on the upper substrate and electrically connected to the upper interconnection layer; a third semiconductor chip disposed above the upper substrate, spaced apart from the second semiconductor chip in a first direction that intersects the vertical direction, and the third semiconductor chip electrically connected to the upper interconnection layer; a molded portion disposed on the lower substrate and covering the first semiconductor chip and having a molded portion footprint different from a footprint of the upper substrate with respect to a plan view; and an auxiliary molded layer filling a space between the molded portion and the upper substrate.

According to example embodiments, a semiconductor package includes a first semiconductor package including a lower substrate and a first semiconductor chip on the lower substrate; a second semiconductor package disposed above the first semiconductor package while being spaced apart from the first semiconductor package in a vertical direction, and the second semiconductor package including an upper substrate, a second semiconductor chip on the upper substrate, and a third semiconductor chip spaced apart from the second semiconductor chip in a first direction, intersecting the vertical direction; connection structures disposed between the first semiconductor package and the second semiconductor package and electrically connecting the first semiconductor package to the second semiconductor package; a molded portion covering an upper surface of the first semiconductor package, a footprint of the first semiconductor package being different than a footprint of the upper substrate with respect to a plan view; and an auxiliary molded layer filled between the molded portion and the second semiconductor package.

According to example embodiments, a semiconductor package includes a lower substrate including a lower interconnection layer and having a first footprint when viewed in a plan view; a first semiconductor chip disposed on the lower substrate and electrically connected to the lower interconnection layer; an upper substrate disposed above and spaced apart from the first semiconductor chip in a vertical direction, the upper substrate including an upper interconnection layer and having a second footprint different from the first footprint when viewed in the plan view; connection structures disposed between the lower substrate and the upper substrate and electrically connecting the lower substrate to the upper substrate; a second semiconductor chip disposed on the upper substrate and electrically connected to the upper interconnection layer; a third semiconductor chip on the upper substrate, spaced apart from the second semiconductor chip in a first direction, intersecting the vertical direction, and electrically connected to the upper interconnection layer; a molded portion covering the first semiconductor chip and disposed on the lower substrate, and the molded portion having a third footprint different than the second footprint with respect to a plan view; and an auxiliary molded layer filled between the molded portion and the upper substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 illustrates a plan view of a semiconductor package according to example embodiments;

FIG. 2A is a cross-sectional view illustrating an example embodiment, taken along line I-I′ of FIG. 1;

FIG. 2B is a cross-sectional view illustrating another embodiment, taken along line I-I′ of FIG. 1;

FIG. 3 is a plan view of a semiconductor package according to another embodiment;

FIG. 4 is a cross-sectional view illustrating an example embodiment, taken along line II-II′ of FIG. 3;

FIGS. 5, 6, 7, 8, 9, 10, and 11 are diagrams illustrating an example embodiment of a method of manufacturing the semiconductor package of FIG. 2A; and

FIGS. 12, 13, and 14 are diagrams illustrating an example embodiment of a method of manufacturing the semiconductor package of FIG. 4.

### DETAILED DESCRIPTION

Hereinafter, example embodiments will be described in more detail with reference to the attached drawings. The same reference numerals are used for the same components in the drawings, and duplicate descriptions for the same components may be omitted. Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

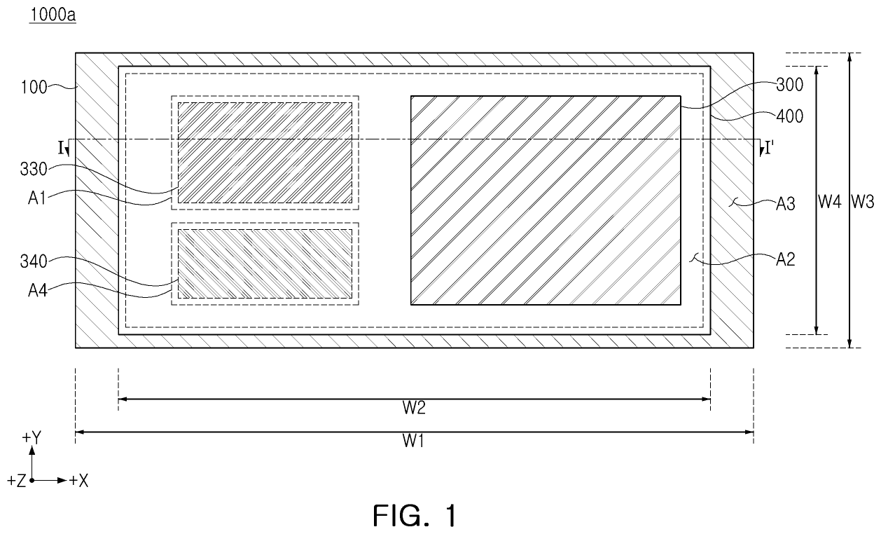

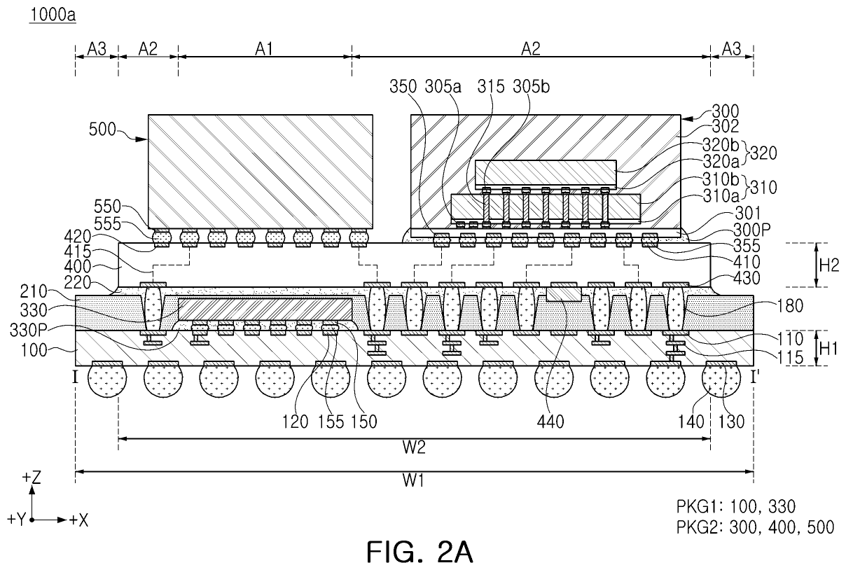

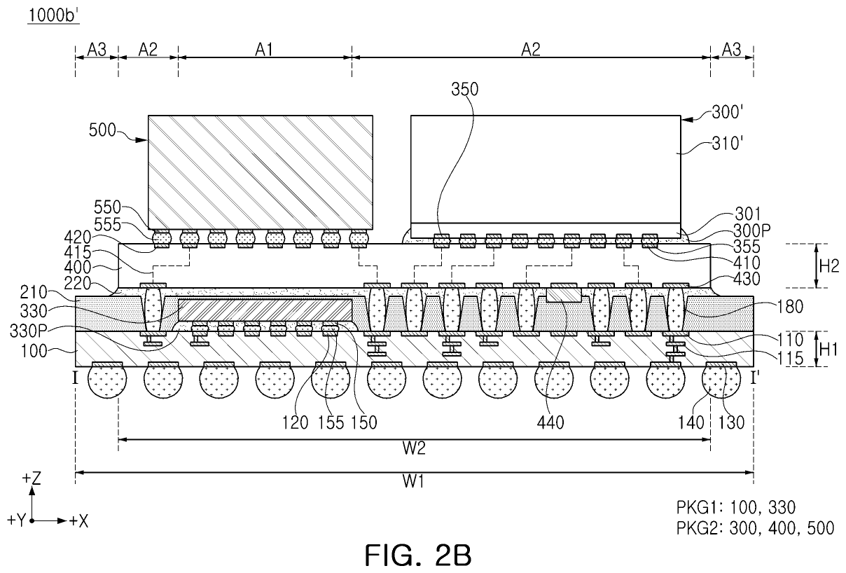

FIG. 1 illustrates a plan view of a semiconductor package according to example embodiments. FIG. 2A is a cross-sectional view illustrating an example embodiment along line I-I′ in FIG. 1.

Referring to FIGS. 1 and 2A, a semiconductor package 1000a may include a lower substrate 100, an upper substrate 400, connection structures 180, a first semiconductor chip 330, a second semiconductor chip 500, a third semiconductor chip 300, a molded portion 210, and an auxiliary molded layer 220.

In an example embodiment, the lower substrate 100 is a support substrate on which the first semiconductor chip 330 is mounted, and may be a substrate for a semiconductor package, including a printed circuit board (PCB), a ceramic substrate, a glass substrate, a tape interconnection substrate, and the like. In an example, the lower substrate 100 may include different materials depending on the type of substrate. For example, when the lower substrate 100 is a printed circuit board, the lower substrate 100 may be in the form of an additional interconnection layer being laminated on one or both sides of a copper clad laminate. In an example, a solder resist layer may be disposed on the lower and upper surfaces of the lower substrate 100.

In an example embodiment, the lower substrate 100 may include an upper surface on which the first upper pads 110 and 120 are disposed, a lower surface on which the first lower pad 130 is disposed, and a side surface connecting the upper surface and the lower surface.

In an example embodiment, the upper surface of the lower substrate 100 may include a first region A1 where the first semiconductor chip 330 is mounted, a second region A2 in which connection structures 180 are arranged surrounding the first region A1, and a third region A3 surrounding the second region A2, but in which the connection structures 180 are not disposed. In an example, the lower substrate 100 may further include a fourth region A4 spaced apart from the first region A1 in the second direction (+Y direction) and in which the fourth semiconductor chip 340 is mounted. The fourth region A4 may be surrounded by the second region A2. In an example, the fourth semiconductor chip 340 may be a memory chip. For example, when the first semiconductor chip 330 is a logic chip, the fourth semiconductor chip 340 may include a memory chip for the first semiconductor chip 330.

In an example embodiment, with respect to a plan view, the footprint of the lower substrate 100 may be larger than the footprint of the upper substrate 400, which will be described later. In an example, the first region A1 and the second region A2 of the lower substrate 100 overlap the upper substrate 400 in a vertical direction (+Z direction), and the third region A3 of the lower substrate 100 may not overlap the upper substrate 400 in the vertical direction (+Z direction).

In an example embodiment, the lower interconnection layer 115 may be buried and disposed within the lower substrate 100. In an example, the lower interconnection layer 115 may be disposed within the lower substrate 100 and include multiple redistribution layers and vias connecting the redistribution layers. The lower interconnection layer 115 may electrically connect the first upper pads 110 and 120 and the first lower pad 130.

In an example embodiment, the first upper pads 110 and 120 may include a 1-1 upper pad 110 disposed on the second region A2 and a 1-2 upper pad 120 disposed on the first region A1. In an example, the first lower pad 130 may be disposed on the lower surface of the lower substrate 100.

In an example embodiment, the first upper pads 110 and 120, the first lower pad 130, and the lower interconnection layer 115 may form an electrical path connecting the upper and lower surfaces of the lower substrate 100. In an example, the first upper pads 110 and 120, the first lower pad 130, and the lower interconnection layer 115 may include a metal material. The metal material may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy containing two or more metals.

In an example embodiment, the semiconductor package 1000a may further include a lower connection bump 140 disposed on the lower surface of the lower substrate 100 and electrically connected to the first lower pad 130. The lower connection bump 140 may include tin (Sn) or an alloy containing tin (Sn) (for example, Sn—Ag—Cu).

In an example embodiment, the first semiconductor chip 330 may be mounted on the first region A1 of the lower substrate 100. The first semiconductor chip 330 may be electrically connected to the lower interconnection layer 115 through first connection patterns, which may include a first connection pad 150 and a first connection bump 155, and the 1-2 upper pad 120. The first connection patterns may be disposed between the first semiconductor chip 330 and the 1-2 upper pads 120. The first connection pad 150 may be disposed on the lower surface of the first semiconductor chip 330 and the first connection bump 155 may be disposed between the 1-2 upper pad 120 and the first connection pad 150.

In an example embodiment, the semiconductor package 1000a may further include a first underfill material layer 330P surrounding at least a portion of the side surface of the first semiconductor chip 330. In an example, the first underfill material layer 330P may fill the space between the lower surface of the first semiconductor chip 330 and the upper surface of the lower substrate 100 and between the first connection patterns. In an example, the first underfill material layer 330P may be disposed and/or formed by a Capillary Underfill (CUF) process, but is not limited thereto. The first underfill material layer 330P may include an insulating resin. For example, the first underfill material layer 330P may include thermosetting resin, thermoplastic resin such as polyimide, or ABF, FR-4, BT, EMC, or prepreg containing inorganic filler or/and glass fiber.

In an example embodiment, the first semiconductor chip 330 may include a communication processor (CP). However, the present inventive concept is not limited thereto, and the first semiconductor chip 330 may include a modem, a central processing unit (CPU), or a graphic processing unit (GPU).

In an example embodiment, the connection structures 180 may be disposed on the second region A2 of the lower substrate 100. Connection structures 180 may be disposed on the 1-1 upper pad 110. The connection structures 180 may surround the first semiconductor chip 330. In an example, the connection structures 180 may include a solder portion. In an example, connection structures 180 may have a spherical or ball shape formed of a low melting point metal such as tin (Sn), indium (In), bismuth (Bi), antimony (Sb), copper (Cu), silver (Ag), zinc (Zn), lead (Pb), or alloys thereof (for example, Sn—Ag—Cu), or the like.

In an example embodiment, the height of the connection structures 180 in the vertical direction (for example, the third direction (+Z direction)) may be higher than the height of the first semiconductor chip 330 in the vertical direction.

In an example embodiment, the upper substrate 400 may be arranged to be vertically spaced apart from the first semiconductor chip 330 on the lower substrate 100. The upper substrate 400 is a support substrate on which the second semiconductor chip 500 and the third semiconductor chip 300 are mounted, and may be a substrate for a semiconductor package, including a printed circuit board (PCB), a ceramic substrate, a glass substrate, a tape interconnection substrate, etc.

In an example embodiment, the upper substrate 400 may include an upper surface on which second upper pads 410 and 420 are disposed, a lower surface on which a second lower pad 430 and a passive element 440 are disposed, and a side surface connecting the upper surface and the lower surface.

In an example embodiment, an upper interconnection layer 415 of the upper substrate 400 may be electrically connected to the lower interconnection layer 115 of the lower substrate 100 through the second lower pad 430 and the connection structures 180 disposed under the upper substrate 400. The second lower pad 430 is disposed on the lower surface of the upper substrate 400 and may overlap the connection structures 180 in a vertical direction (for example, the third direction (+Z direction)).

In an example embodiment, the upper interconnection layer 415 may be buried and disposed within the upper substrate 400. In an example, the upper interconnection layer 415 is buried in the upper substrate 400 and may include multiple redistribution layers and vias connecting the same. The upper interconnection layer 415 may electrically connect the second upper pads 410 and 420 and the second lower pad 430.

In an example embodiment, the second upper pads 410 and 420 may include a 2-1 upper pad 410 and a 2-2 upper pad 420 spaced apart from the 2-1 upper pad 410 in a first direction (+X direction). In an example, the 2-1 upper pad 410 may overlap the connection structures 180 in the vertical direction (+Z direction). The 2-2 upper pad 420 may at least partially overlap the first semiconductor chip 330 in the vertical direction (+Z direction).

In an example embodiment, the second upper pads 410 and 420, the second lower pad 430, and the upper interconnection layer 415 may form an electrical path connecting the upper and lower surfaces of the upper substrate 400. In an example, the second upper pads 410 and 420, the second lower pad 430, and the upper interconnection layer 415 may include a metal material.

In an example embodiment, the passive element 440 may be disposed on the lower surface of the upper substrate 400. The passive element 440 may be disposed on the lower surface of the upper substrate 400 and surrounded by connection structures 180. As the passive element 440 is disposed on the bonding pad disposed on the lower surface of the upper substrate 400, the connection path with the connection structures 180 may be minimized. In an example, the passive element 440 may overlap the second region A2 of the lower substrate 100 in the vertical direction (+Z direction).

In an example embodiment, when viewed in a plan view, the footprint of the upper substrate 400 may be smaller than the footprint of the lower substrate 100. In an example, the upper substrate 400 may overlap the first region A1 and the second region A2 of the lower substrate 100 in the vertical direction (+Z direction). The upper substrate 400 may not overlap the third region A3 of the lower substrate 100 in the vertical direction (+Z direction).

In an example embodiment, the lower substrate 100 has a first width W1 in a first direction (+X direction), and may have a third width W3 in a second direction (+Y direction) that intersects the first direction (+X direction). The first width W1 may be larger than the third width W3.

In an example embodiment, the upper substrate 400 may have a second width W2 in the first direction (+X direction) and a fourth width W4 in the second direction (+Y direction). The second width W2 may be larger than the fourth width W4.

In an example, the first width W1 of the lower substrate 100 may be greater than the second width W2 of the upper substrate 400. The third width W3 of the lower substrate 100 may be larger than the fourth width W4 of the upper substrate 400.

In an example embodiment, the second height H2 in the vertical direction (for example, third direction (+Z direction)) of the upper substrate 400 may be higher than the first height H1 in the vertical direction of the lower substrate 100. In an example, the number of interconnection layers included in the upper substrate 400 may be greater than the number of interconnection layers included in the lower substrate 100.

In an example embodiment, the second semiconductor chip 500 may be disposed on the 2-2 upper pad 420. The second semiconductor chip 500 may be electrically connected to the upper interconnection layer 415 of the upper substrate 400 through second connection patterns and the 2-2 upper pad 420 disposed on the lower surface of the second semiconductor chip 500. The second connection patterns may be disposed between the second semiconductor chip 500 and the 2-2 upper pad 420. The second connection patterns may include a second connection pad 550 disposed on the lower surface of the second semiconductor chip 500, and a second connection bump 555 disposed between the 2-2 upper pad 420 and the second connection pad 550.

In an example embodiment, the second semiconductor chip 500 may be a memory chip. The memory chip may include a volatile memory chip, such as a Dynamic Random Access Memory (DRAM) or a Static Random Access Memory (SRAM), or a non-volatile memory chip such as a Phase-change Random Access Memory (PRAM), a Magnetoresistive Random Access Memory (MRAM), a Ferroelectric Random Access Memory (FeRAM), or a Resistive Random Access Memory (RRAM).

In an example embodiment, the second semiconductor chip 500 may overlap at least a portion of the first semiconductor chip 330 in the vertical direction (+Z direction).

In an example embodiment, the third semiconductor chip 300 may be disposed on the 2-1 upper pad 410. The third semiconductor chip 300 may be arranged to be spaced apart from the second semiconductor chip 500 in a first direction (+X direction). The third semiconductor chip 300 may be placed at the same level as the second semiconductor chip 500 on the upper surface of the upper substrate 400. In an example, the third semiconductor chip 300 may overlap the connection structures 180 in the vertical direction (+Z direction). Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

In an example embodiment, the third semiconductor chip 300 may be electrically connected to the upper interconnection layer 415 of the upper substrate 400 through third connection patterns, which may include a third connection pad 350 and a third connection bump 355, disposed on the lower surface of the third semiconductor chip 300. The third connection patterns may be disposed between the third semiconductor chip 300 and the 2-1 upper pad 410. The third connection pad 350 may be disposed on the lower surface of the third semiconductor chip 300 and the third connection bump 355 may be disposed between the third connection pad 350 and the 2-1 upper pad 410.

In an example embodiment, the third semiconductor chip 300 may include a substrate 301, a plurality of semiconductor dies, die connection patterns 305a and 305b, and a sealant 302.

In an example embodiment, the substrate 301 may be a substrate on which a plurality of semiconductor dies are mounted. The substrate 301 may be a package substrate including a lower interconnection layer for redistributing electrical connections of the plurality of dies. The substrate 301 may have similar characteristics to the lower substrate 100 and/or the upper substrate 400. The substrate 301 may be placed on the 2-1 upper pad 410.

In an example embodiment, the plurality of semiconductor dies may be sequentially arranged in the vertical direction (+Z direction) on the substrate 301 (e.g., the semiconductor dies may be stacked in the vertical direction). In an example, the plurality of semiconductor dies may include a first die 310 and a second die 320. The first die 310 and the second die 320 may be sequentially disposed (stacked) on the substrate 301 in the vertical direction (+Z direction). The number of semiconductor dies stacked is illustrated as two, but is not limited thereto, and other embodiments may include one semiconductor die or three or more semiconductor dies.

In an example embodiment, the first die 310 may include a first base substrate 310a, a first circuit layer 310b disposed on the first base substrate 310a, and through-electrodes 315 penetrating the first die 310 in the vertical direction (+Z direction). The first die 310 may be disposed on the substrate 301 and electrically connected to the substrate 301 through the first die connection pattern 305a disposed on the lower surface of the first base substrate 310a.

In an example embodiment, the second die 320 may include a second base substrate 320a and a second circuit layer 320b disposed on the second base substrate 320a. The second die 320 may be disposed on the first die 310 through the second die connection pattern 305b disposed on the lower surface of the second base substrate 320a and may be electrically connected to the first die 310.

In an example embodiment, the first and second base substrates 310a and 320a may include a semiconductor element such as silicon (Si) or germanium (Ge), and may include a compound semiconductor such as silicon carbide (SiC), gallium arsenide (GaAs), indium arsenide (InAs), or indium phosphide (InP).

In an example embodiment, each of the first and second circuit layers 310b and 320b may be disposed on the active side of the first and second base substrates 310a and 320a and may include an interlayer insulating layer and an interconnection structure.

In an example embodiment, the through-electrodes 315 may penetrate the first die 310 and electrically connect the first and second die connection patterns 305a and 305b.

In an example embodiment, the sealant 302 may surround the substrate 301 and the plurality of semiconductor dies, such as first die 310 and second die 320.

In an example embodiment, the third semiconductor chip 300 may include a logic chip, a processor chip, or a controller chip. In an example, the third semiconductor chip 300 may include an application processor (AP), a mobile AP, a chip set, or a set of chips. The third semiconductor chip 300 may be a semiconductor chip that performs a different function from the first semiconductor chip 330.

In an example embodiment, the width of the third semiconductor chip 300 in the first direction (+X direction) may be larger than the width of the first semiconductor chip 330 and the second semiconductor chip 500 in the first direction (+X direction). In an example, the width of the first semiconductor chip 330 in the first direction (+X direction) may be smaller than the width of the second semiconductor chip 500 in the first direction (+X direction).

In an example embodiment, the semiconductor package 1000a may further include a second underfill material layer 300P surrounding the side surface of the third semiconductor chip 300. The second underfill material layer 300P may fill the space between the lower surface of the third semiconductor chip 300 and the upper surface of the upper substrate 400 and the third connection patterns. In an example, the second underfill material layer 300P may be disposed and/or formed by a capillary underfill (CUF) process, but is not limited thereto.

In an example embodiment, the semiconductor package 1000a may include a first semiconductor package PKG1 and a second semiconductor package PKG2. In an example, the lower substrate 100 and the first semiconductor chip 330 may form the first semiconductor package PKG1. In an example, the upper substrate 400, the second semiconductor chip 500, and the third semiconductor chip 300 may form the second semiconductor package PKG2. The first semiconductor package PKG1 and the second semiconductor package PKG2 may be electrically connected through connection structures 180. In an example, the width of the first semiconductor package PGK1 in the first direction (+X direction) may correspond to the width of the lower substrate 100 in the first direction (+X direction). The width of the second semiconductor package PKG2 in the first direction (+X direction) may correspond to the width of the upper substrate 400 in the first direction (+X direction).

In an example embodiment, the molded portion 210 may be disposed on the upper surface of the lower substrate 100. The molded portion 210 may be disposed on the upper surface of the lower substrate 100 to cover the first semiconductor chip 330 and the first underfill material layer 330P. In an example, the molded portion 210 may completely cover the upper surface of the lower substrate 100. The molded portion 210 may surround at least a portion of the side surface of the connection structures 180 extending in the vertical direction (for example, the third direction (+Z direction)). In an example, the molded portion 210 may have a molded underfill (MUF) structure.

In an example embodiment, the molded portion 210 may include a lower surface in contact with the lower substrate 100, an upper surface opposing the lower surface, and a side connecting the lower surface and the upper surface.

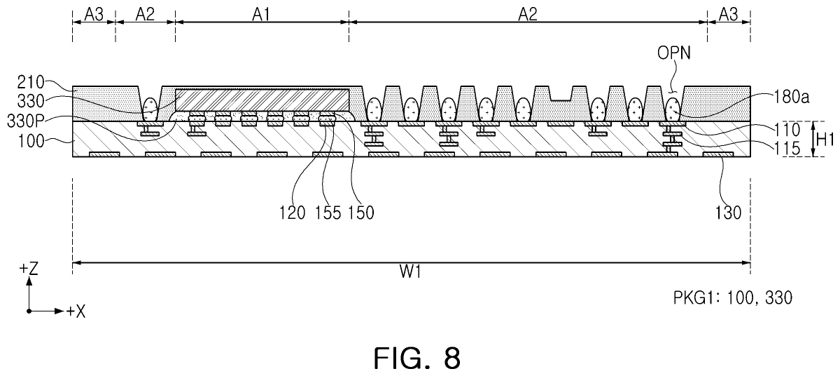

In an example embodiment, the molded portion 210 may include openings (for example, openings OPN in FIG. 8) to accommodate the connection structures 180. At least a portion of the connection structures 180 may be disposed within the opening due to the opening.

In an example embodiment, a portion of the side surface extending in the vertical direction of the connection structures 180 may be covered by the molded portion 210 and the remaining portion may be covered by the auxiliary molded layer 220.

The width of the molded portion 210 in the first direction (+X direction) may be different from the width of the upper substrate 400 in the first direction (+X direction). The width of the molded portion 210 in the first direction (+X direction) may be greater than the width of the upper substrate 400 in the first direction (+X direction). In an example, the width of the molded portion 210 in the first direction (+X direction) may be equal to or substantially equal to the width of the lower substrate 100 in the first direction (+X direction). In an example, the area of the upper surface of the molded portion 210 may be different from the area of the lower surface of the upper substrate 400. In an example, the area of the upper surface of the molded portion 210 may be larger than the area of the lower surface of the upper substrate 400 when viewed in a plan view.

In an example embodiment, the auxiliary molded layer 220 may be disposed between the molded portion 210 and the upper substrate 400 to fill the space between the molded portion 210 and the upper substrate 400. The auxiliary molded layer 220 may fill the groove (or recess) formed in the molded portion 210 adjacent to the side surface of the connection structures 180.

In an example, the auxiliary molded layer 220 may be disposed on at least one area of the upper surface of the molded portion 210 disposed on the third region A3. The auxiliary molded layer 220 may not be disposed on the side of the molded portion 210 and the side of the upper substrate 400. The auxiliary molded layer 220 may fill the space between the lower surface of the upper substrate 400 and the molded portion 210. In another example, the auxiliary molded layer 220 is not disposed on the side of the molded portion 210, but may be disposed on at least a portion of the side of the upper substrate 400.

Each of the molded portion 210, the auxiliary molded layer 220, and the underfill material layer may be a single continuous homogenous layer (formed of the same base material throughout). For example, these patterns may each be formed with a single corresponding process (e.g., in situ-in a chamber without vacuum break to the chamber).

In an example embodiment, the width of the molded portion 210 in the first direction (+X direction) may be greater than the width of the auxiliary molded layer 220 in the first direction (+X direction). In the semiconductor package 1000a according to example embodiments, the upper substrate 400 on which the second semiconductor chip 500 and the third semiconductor chip 300 are mounted may be disposed on the lower substrate 100 on which the first semiconductor chip 330 is mounted, through connection structures 180, without a separate interposer substrate. Accordingly, a semiconductor package with improved integration may be provided.

The semiconductor package 1000a according to example embodiments may include a first semiconductor package PKG1 including a lower substrate 100 having a first area, and the first semiconductor package PKG1, and a second semiconductor package PKG2 arranged to be spaced apart in the vertical direction (+Z direction) and including an upper substrate 400 having a second footprint different that the first footprint. Additionally, in the space between the first semiconductor package PKG1 and the second semiconductor package PKG2, as the molded portion 210 and the auxiliary molded layer 220 that protect the first semiconductor chip 330 and the connection structures 180 are disposed, the bonding force between the first semiconductor package PKG1 and the second semiconductor package PKG2 may be increased, thereby providing a semiconductor package with improved reliability.

FIG. 2B is a cross-sectional view illustrating another embodiment along line I-I′ in FIG. 1.

Referring to FIG. 2B, the configurations excluding the third semiconductor chip 300′ may be the same as or correspond to the configurations illustrated in FIG. 2A.

Referring to FIG. 2B, the third semiconductor chip 300′ may include a substrate 301 and a semiconductor die 310′ disposed on the upper surface of the substrate 301. The semiconductor die 310′ may be mounted on the substrate 301 using a flip-chip method, but is not limited thereto, and may be connected through bumps in the form of balls or posts.

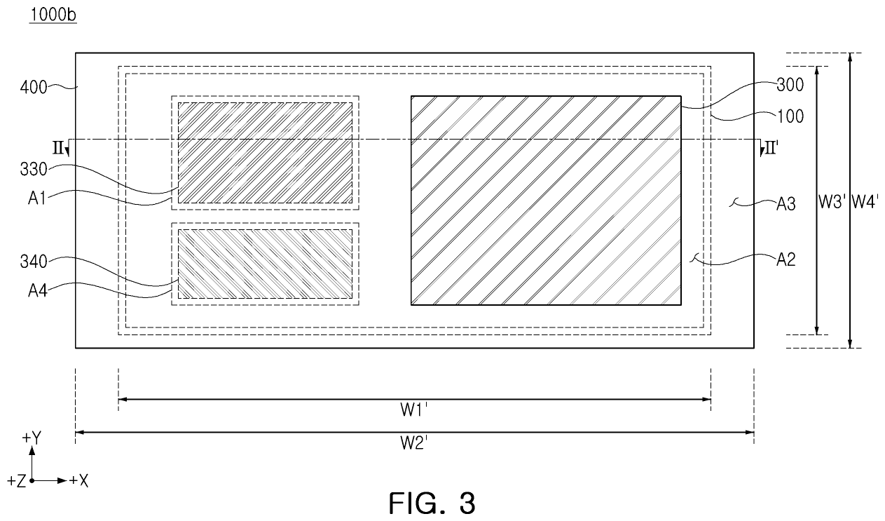

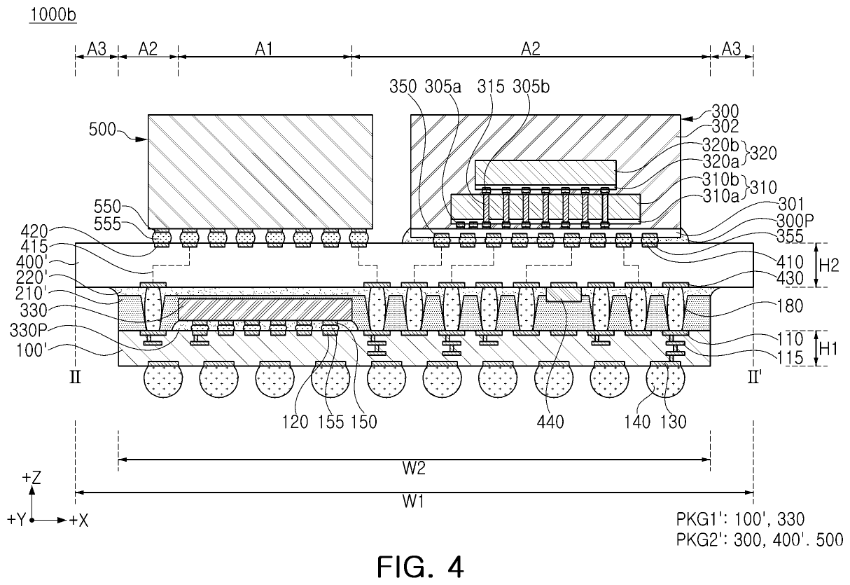

FIG. 3 is a plan view of a semiconductor package according to another embodiment. FIG. 4 is a cross-sectional view illustrating an example embodiment along line II-II′ in FIG. 3.

The semiconductor package of FIG. 3 except for the lower substrate 100′, the upper substrate 400′, the molded portion 210′, and the auxiliary molded layer 220′ as illustrated in FIG. 3 may be the same as or correspond to the configurations illustrated in FIGS. 1 and 2A. Redundant descriptions of the same or corresponding components may be omitted.

Referring to FIGS. 3 and 4, a semiconductor package 1000b may include a lower substrate 100′, an upper substrate 400′, connection structures 180, a first semiconductor chip 330, a second semiconductor chip 500, a third semiconductor chip 300, a molded portion 210′ and an auxiliary molded layer 220′.

In an example embodiment, the footprint of the lower substrate 100′ may be smaller than the footprint of the upper substrate 400′ when viewed in a plan view. In an example, the lower substrate 100′ may overlap the upper substrate 400′ in the vertical direction (+Z direction). For example, the lower substrate 100′ may be completely covered by the upper substrate 400′.

In an example embodiment, the upper surface of the lower substrate 100′ may include a first region A1 where the first semiconductor chip 330 is mounted, and a second region A2 in which connection structures 180 surrounding the first region A1 are disposed. In an example, the lower substrate 100′ may be spaced apart from the first region A1 in the second direction (+Y direction) and may further include a fourth region A4 on which the fourth semiconductor chip 340 is mounted. The fourth region A4 may be surrounded by the second region A2.

In an example embodiment, the upper substrate 400′ may be arranged to be spaced apart from the first semiconductor chip 330 in the vertical direction (+Z direction) on the lower substrate 100′. The upper substrate 400′ may include an overlapping region that overlaps the first region A1 and the second region A2 of the lower substrate 100′ in the vertical direction (+Z direction), and a non-overlapping region A3 that does not overlap the lower substrate 100′ in the vertical direction (+Z direction).

In an example embodiment, the lower substrate 100′ has a first width W1′ in a first direction (+X direction), and may have a third width W3′ in a second direction (+Y direction) that intersects the first direction (+X direction). The first width W1′ may be larger than the third width W3′.

In an example embodiment, the upper substrate 400′ may have a second width W2′ in the first direction (+X direction) and a fourth width W4′ in the second direction (+Y direction). The second width W2′ may be larger than the fourth width (W4′).

In an example embodiment, the first width W1′ of the lower substrate 100′ may be smaller than the second width W2′ of the upper substrate 400′. The third width W3′ of the lower substrate 100′ may be smaller than the fourth width W4′ of the upper substrate 400′.

In an example embodiment, the second height H2 in the vertical direction (+Z direction) of the upper substrate 400′ may be higher than the first height H1 in the vertical direction of the lower substrate 100′. In an example, the number of interconnection layers included in the upper substrate 400′ may be greater than the number of interconnection layers included in the lower substrate 100′.

In an example embodiment, the semiconductor package 1000b may include a first semiconductor package PKG1′ and a second semiconductor package PKG2′. In an example, the lower substrate 100′ and the first semiconductor chip 330 may form a first semiconductor package PKG1′. In an example, the upper substrate 400′, the second semiconductor chip 500, and the third semiconductor chip 300 may form a second semiconductor package PKG2′. The first semiconductor package PKG1′ and the second semiconductor package PKG2′ may be electrically connected through connection structures 180.

In an example embodiment, the molded portion 210′ may be disposed on the upper surface of the lower substrate 100′. The molded portion 210′ may be disposed on the upper surface of the lower substrate 100′ to cover the first semiconductor chip 330 and the first underfill material layer 330P. In an example, the molded portion 210′ may surround at least a portion of the side surface of the connection structures 180 extending in the vertical direction (for example, the third direction (+Z direction)). In an example, the molded portion 210′ may have a molded underfill (MUF) structure.

In an example embodiment, the width of the molded portion 210′ in the first direction (+X direction) may be smaller than the width of the upper substrate 400′ in the first direction (+X direction). In an example, the footprint of the upper surface of the molded portion 210′ may be smaller than the footprint of the lower surface of the upper substrate 400′ when viewed in a plan view.

In an example embodiment, the auxiliary molded layer 220′ may be disposed between the molded portion 210′ and the upper substrate 400′ to fill the space between the molded portion 210′ and the upper substrate 400′. The auxiliary molded layer 220′ may fill the space between the molded portion 210′ and the upper substrate 400′. In an example, the auxiliary molded layer 220′ may completely cover the upper surface of the molded portion 210′, but the auxiliary molded layer 220′ may not be disposed on the side of the molded portion 210′ and the side of the upper substrate 400′. In another example, the auxiliary molded layer 220′ may not be disposed on the side of the upper substrate 400′, but may be disposed on at least a portion of the side of the molded portion 210′.

In an example embodiment, the auxiliary molded layer 220′ may completely cover the mold portion 210′. In an example, the auxiliary molded layer 220′ may be disposed on at least one area of the non-overlapping region A3 of the upper substrate 400′.

The semiconductor package 1000b according to example embodiments may include a lower substrate 100′ on which the first semiconductor chip 330 is mounted, and an upper substrate 400′ that is larger than the lower substrate 100′ and on which the second semiconductor chip 500 and the third semiconductor chip 300 are mounted, thereby providing a semiconductor package with various specifications.

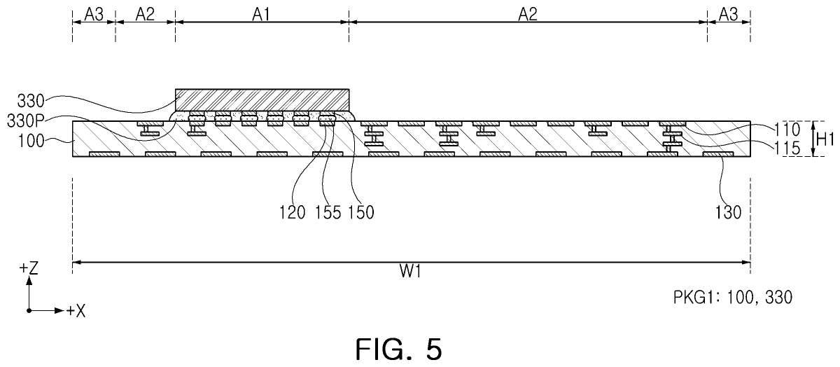

FIGS. 5 to 11 are diagrams illustrating an example embodiment of the method for manufacturing the semiconductor package of FIG. 2A.

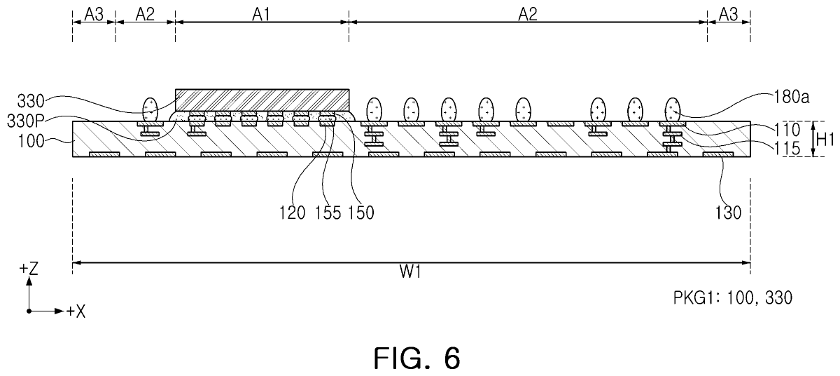

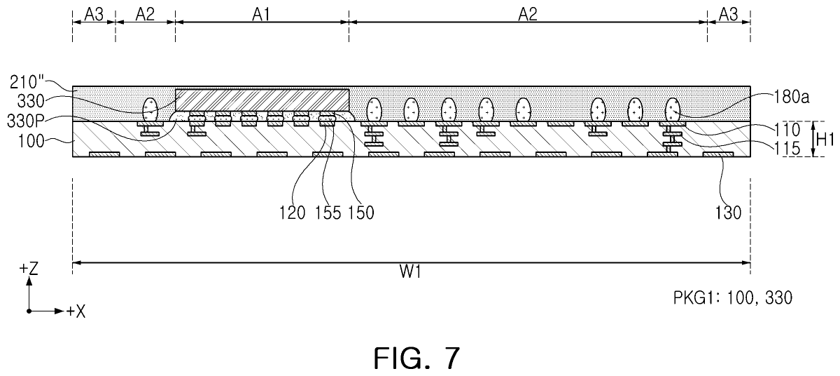

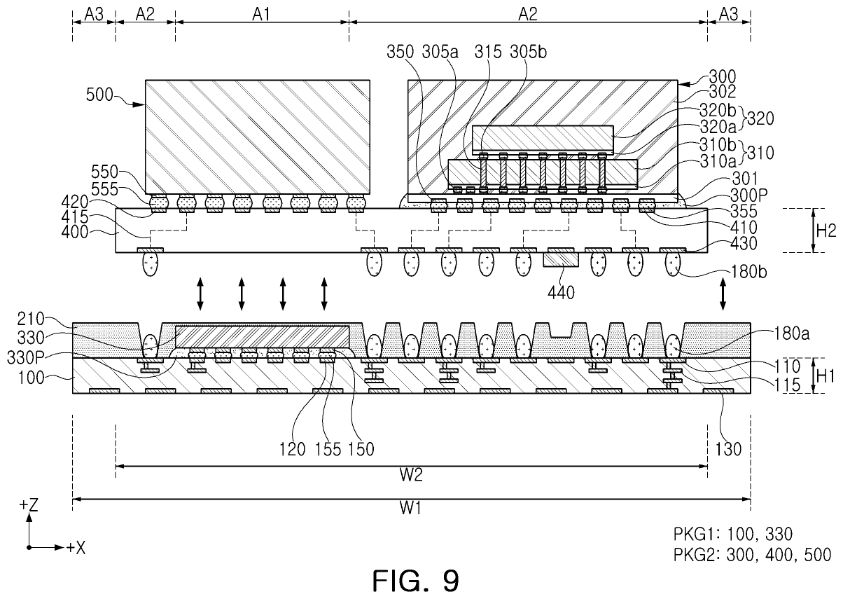

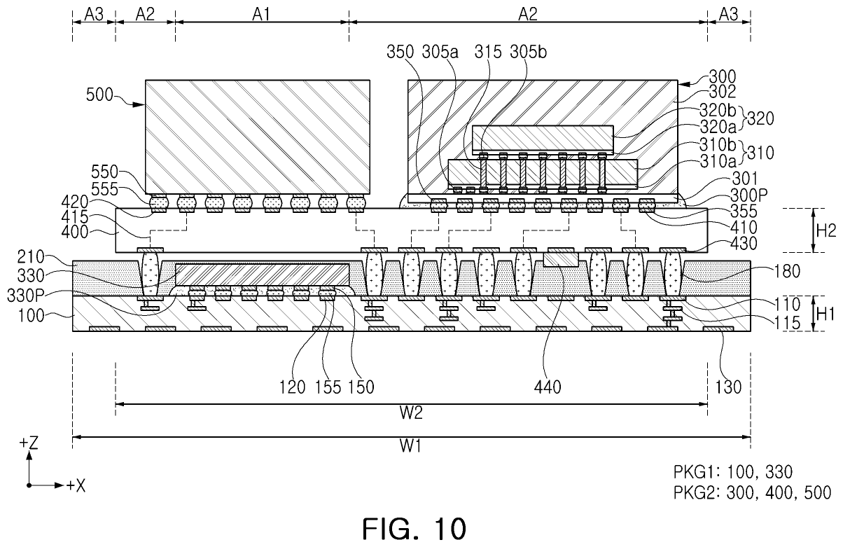

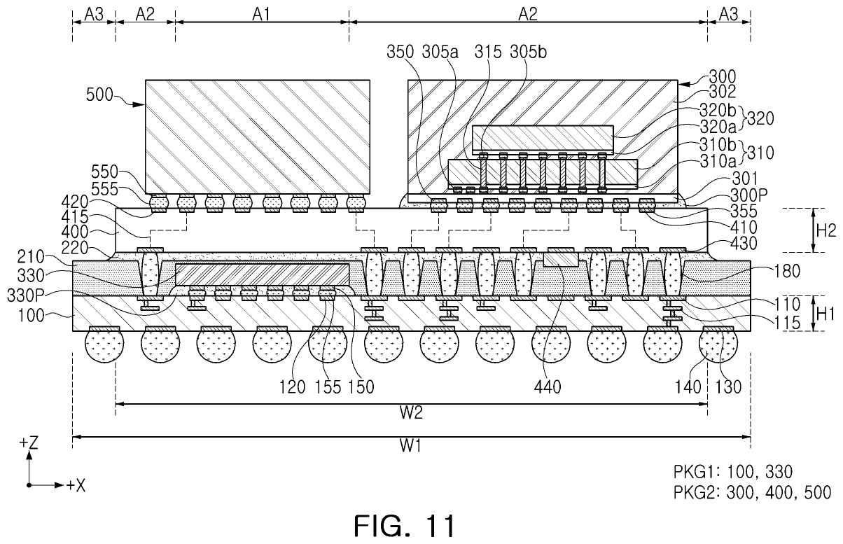

A method of manufacturing a semiconductor package 1000a according to example embodiments may include forming a first semiconductor package PKG1 including a lower substrate 100 and a first semiconductor chip 330 mounted on the lower substrate 100 (see FIG. 5), forming lower connection structures 180a on the second region A2 of the first semiconductor package PKG1 (see FIG. 6), forming a molded portion 210″ covering the first semiconductor chip 330 and the lower connection structures 180a on the lower substrate 100 (see FIG. 7), forming an opening (OPN) exposing the lower connection structures 180a by performing a laser drilling process on the molded portion 210″ (see FIG. 8), forming upper connection structures 180b below the second semiconductor package PKG2 including the upper substrate 400 and the second semiconductor chip 500 and the third semiconductor chip 300 mounted on the upper substrate 400, above the first semiconductor package PKG1 (see FIG. 9), forming connection structures 180 by joining lower connection structures 180a exposed on the upper surface of the second region A2 of the first semiconductor package PKG1, and upper connection structures 180b formed on the lower surface of the second semiconductor package PKG2 at the first temperature (see FIG. 10), and forming an auxiliary molded layer 220 between the molded portion 210 and the second semiconductor package PKG2 (see FIG. 11).

Referring to FIG. 5, as the first semiconductor chip 330 is mounted on the lower substrate 100, a first semiconductor package PKG1 may be formed. A first semiconductor chip 330 may be formed on the first region A1 of the upper surface of the first lower substrate 100. Forming the first semiconductor package PKG1 may further include forming a first underfill material layer 330P that fills the space between the lower surface of the first semiconductor chip 330 and the lower substrate 100.

Referring to FIG. 6, lower connection structures 180a may be formed on the second region A2 of the upper surface of the lower substrate 100. The lower connection structures 180a may include solder balls. The lower connection structure 180a may be formed on the 1-1 upper pad 110. The lower connection structures 180a may surround the first semiconductor chip 330. The lower connection structures 180a may not be formed on the third region A3 on the upper surface of the lower substrate 100.

Referring to FIG. 7, a molded portion 210″ covering the first semiconductor chip 330 and the lower connection structures 180a may be formed on the upper surface of the lower substrate 100. The molded portion 210″ may be formed through a molded underfill (MUF) process. In an example, the molded portion 210″ may completely cover the upper surface of the lower substrate 100.

Referring to FIG. 8, the semiconductor package manufacturing method involves performing a laser drilling process (LDP) on the molded portion 210″ to form an opening (OPN) exposing the lower connection structures 180a. The opening OPN may be formed so that the upper surface of the lower substrate 100 is not exposed. The lower connection structures 180a may be exposed through the opening OPN. In an example, the width of the upper part of the opening OPN may be wider than the width of the lower part of the opening OPN.

Referring to FIG. 9, upper connection structures 180b may be formed on the lower surface of the second semiconductor package PKG2. The upper connection structures 180b may be formed to overlap the lower connection structures 180a on the second region A2 of the upper surface of the first semiconductor package PKG1 in the vertical direction (+Z direction). In an example, the second semiconductor package PKG2 may be a semiconductor package that is manufactured in advance. The second semiconductor package PKG2 may include an upper substrate 400, a second semiconductor chip 500 mounted on the upper substrate 400, and a third semiconductor chip 300 spaced apart from the second semiconductor chip 500 in a first direction (+X direction).

In an example embodiment, the second height H2 in the vertical direction (+Z direction) of the upper substrate 400 of the second semiconductor package PKG2 may be thicker than the first height H1 in the vertical direction (+Z direction) of the lower substrate 100 of the first semiconductor package PKG2.

In an example embodiment, a passive element 440 surrounded by the upper connection structures 180b may be formed on the lower surface of the second semiconductor package PKG2. The passive element 440 may include a capacitor.

Referring to FIGS. 9 and 10, lower connection structures 180a exposed through the opening OPN of the molded portion 210 on the second region A2 of the upper surface of the first semiconductor package PKG1, and the upper connection structures 180b formed on the lower surface of the second semiconductor package PKG2 may be bonded to each other at the first temperature. The lower connection structures 180a and the upper connection structures 180b may be bonded in the vertical direction (+Z direction) at the first temperature to form the connection structures 180. The first temperature may be about 160° C.

Referring to FIG. 11, an auxiliary molded layer 220 may be formed between the molded portion 210 and the second semiconductor package PKG2. An auxiliary molded layer 220 may be injected between the molded portion 210 and the upper substrate 400. The auxiliary molded layer 220 may include an insulating resin like the first underfill material layer 330P. For example, the first underfill material layer 330P may include a thermosetting resin, a thermoplastic resin such as polyimide, or ABF, FR-4, BT, EMC, or prepreg containing inorganic filler or/and glass fiber. In an example, the auxiliary molded layer 220 may not be formed on the side of the molded portion 210 and the side of the upper substrate 400. In an example, the auxiliary molded layer 220 may fill the space between the lower surface of the upper substrate 400 and the molded portion 210 to support and/or protect the semiconductor package.

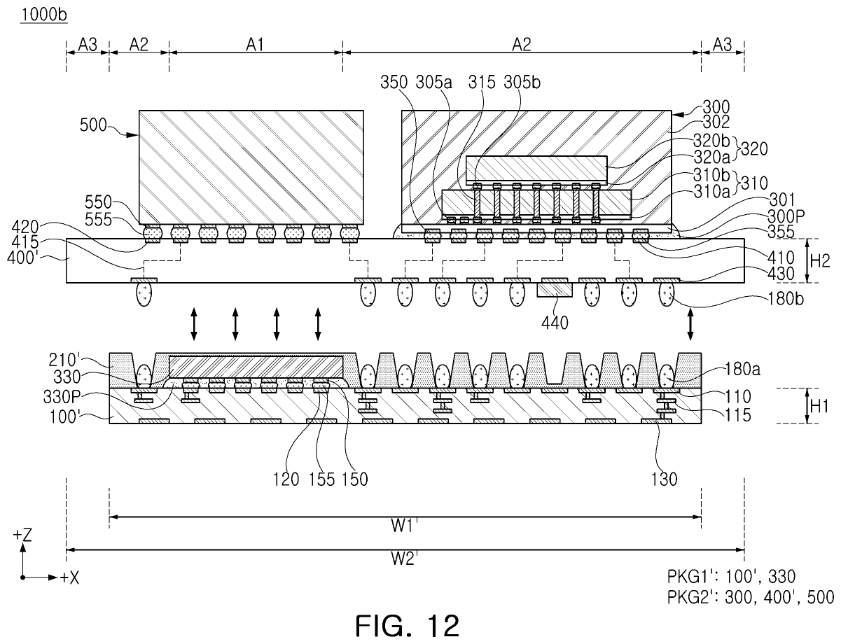

FIGS. 12 to 14 are diagrams illustrating an example embodiment of the method for manufacturing the semiconductor package of FIG. 4.

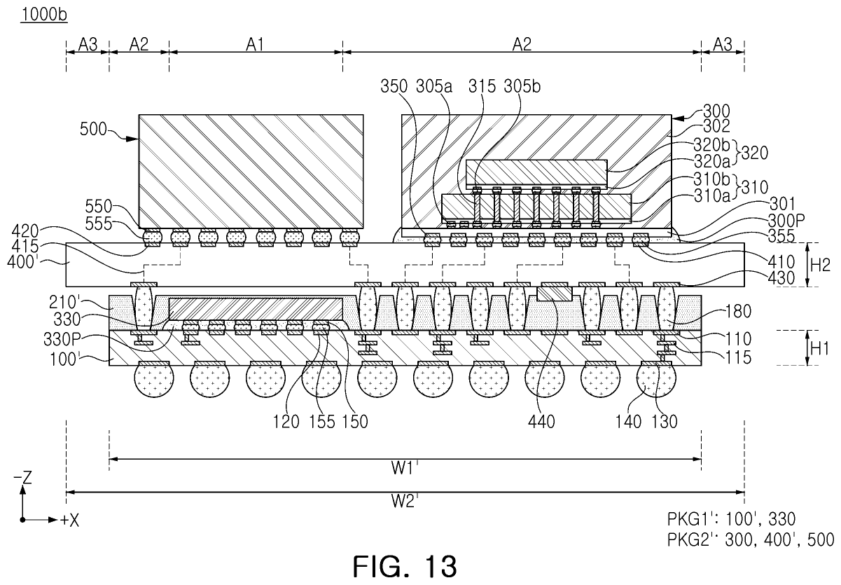

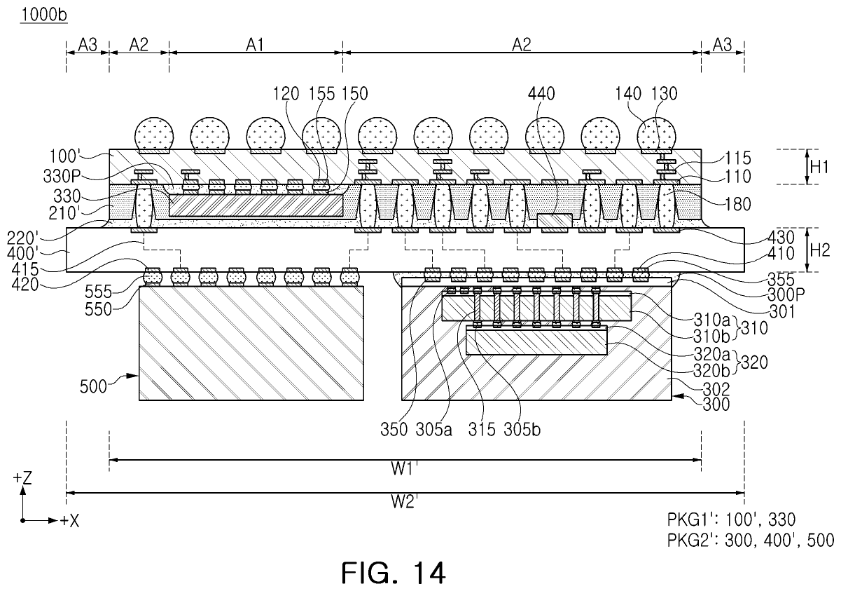

The method of manufacturing a semiconductor package may include forming upper connection structures 180b below the second semiconductor package PKG2′ including the upper substrate 400′ and the second semiconductor chip 500 and the third semiconductor chip 300 mounted on the upper substrate 400′, above the first semiconductor package PKG1′ of the semiconductor package 1000b according to example embodiments (see FIG. 12), forming connection structures 180 by joining lower connection structures 180a exposed on the upper surface of the second region A2 of the first semiconductor package PKG1′, and upper connection structures 180b formed on the lower surface of the second semiconductor package PKG2′ at the first temperature (see FIG. 13), and inverting the semiconductor package 1000b so that the first semiconductor package PKG1′ is placed on the second semiconductor package PKG2′ and injecting the auxiliary molded layer 220 between the molded portion 210 and the second semiconductor package PKG2′ (see FIG. 14).

In an example embodiment, prior to forming the upper connection structures 180b of the second semiconductor package PKG2′, forming a first semiconductor package PKG1′ including the lower substrate 100′ and a first semiconductor chip (330) mounted on the lower substrate 100′, forming lower connection structures 180a on the second region A2 of the first semiconductor package PKG1′, forming a molded portion (for example, molded portion 210″ in FIG. 7) covering the first semiconductor chip 330 and the lower connection structures 180a on the lower substrate 100′, and performing a laser drilling process on the molded portion 210″ to form an opening (for example, opening (OPN) in FIG. 8) exposing the upper surface of the lower connection structures 180a, may be preceded. The processes preceding the step of forming the upper connection structures 180b of the second semiconductor package PKG2′ may be the same as or substantially the same as the manufacturing process of the semiconductor package 1000a (see FIGS. 5 to 8).

Referring to FIG. 12, on the first semiconductor package PKG1′, a second semiconductor package PKG2′ may be disposed to completely cover the first semiconductor package PKG1′ in the vertical direction. Upper connection structures 180b may be formed on the lower surface of the second semiconductor package PKG2′. The upper connection structures 180b may be formed to overlap the lower connection structures 180a on the second region A2 of the upper surface of the first semiconductor package PKG1′ in the vertical direction (+Z direction).

Referring to FIG. 13, lower connection structures 180a exposed on the second region A2 of the upper surface of the first semiconductor package PKG2 and upper connection structures formed on the lower surface of the second semiconductor package PKG2 180b may be bonded at the first temperature. The lower connection structures 180a and the upper connection structures 180b may be bonded in the vertical direction (+Z direction) at the first temperature to form the connection structures 180. The first temperature may be about 160° C.

Referring to FIG. 14, the first semiconductor package PKG1′ is placed on the second semiconductor package PKG2′ (−Z direction). The first semiconductor package PKG1′ and the second semiconductor package PKG2′ coupled by the connection structures 180 may be inverted. After the first semiconductor package PKG1′ and the second semiconductor package PKG2′ are inverted, an auxiliary molded layer 220′ that fills the space between the molded portion 210′ and the upper surface of the upper substrate 400 may be injected.

In an example embodiment, when viewed in a plan view, such as when viewed in the vertical direction (+Z direction), since the footprint of the second semiconductor package PKG2′ is larger than the footprint of the first semiconductor package PKG1′, the first semiconductor package PKG1′ and the second semiconductor package PKG2′ may be inverted so that the first semiconductor package PKG1′ is placed on the second semiconductor package PKG2′ (−Z direction), to stably inject the auxiliary molded layer 220′ between the molded portion 210′ and the upper surface (−Z direction) of the upper substrate 400′.

In an example embodiment, the auxiliary molded layer 220′ may be disposed on a portion of the upper substrate 400′ protruding into the non-overlapping region A3. The auxiliary molded layer 220′ may not be formed on the side of the molded portion 210′ and the side of the upper substrate 400′.

In the method of manufacturing a semiconductor package according to example embodiments, a first semiconductor package PKG1 including a lower substrate 100 having a first area, and a second semiconductor package PKG2 including an upper substrate 400 having a second area different from the first area may be combined in a package-on-package (POP) method, thereby providing semiconductor packages with various specifications. In addition, in addition to the molded portion 210 that protects the first semiconductor chip 330 between the lower substrate 100 and the upper substrate 400, by forming the auxiliary molded layer 220 to fill the space between the molded portion and the upper substrate 400, a semiconductor package having improved reliability may be provided.

As set forth above, in a semiconductor package according to example embodiments, as an upper substrate on which second and third semiconductor chips are disposed is located directly on a lower substrate on which the first semiconductor chip is disposed, a separate interposer substrate is not required, and thus, the size of the semiconductor package may be reduced. Accordingly, a semiconductor package having improved integration may be provided.

A semiconductor package according to example embodiments further includes, in addition to a molded portion protecting a first semiconductor chip, an auxiliary molded layer filling the space between a lower package and an upper package on the molded portion, thereby providing a semiconductor package having improved structural reliability.

In a semiconductor package according to example embodiments, an upper substrate having a second size different from a first size may be disposed on a lower substrate having the first size, thereby providing a semiconductor package satisfying various specifications.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a lower substrate having an upper surface including a first region and a second region surrounding the first region, and including a lower interconnection layer;
a first semiconductor chip disposed on the lower substrate in the first region and electrically connected to the lower interconnection layer;
an upper substrate disposed above the lower substrate and spaced apart from the first semiconductor chip in a vertical direction and including an upper interconnection layer;
connection structures disposed on the lower substrate in the second region and electrically connecting the lower substrate to the upper substrate;
a second semiconductor chip disposed on the upper substrate and electrically connected to the upper interconnection layer;
a third semiconductor chip disposed above the upper substrate, spaced apart from the second semiconductor chip in a first direction that intersects the vertical direction, and electrically connected to the upper interconnection layer;
a molded portion disposed on the lower substrate and covering the first semiconductor chip, and a footprint of the molded portion being different than a footprint of the upper substrate with respect to a plan view; and
an auxiliary molded layer filling a space between the molded portion and the upper substrate.

2. The semiconductor package of claim 1, wherein a first thickness of the lower substrate in the vertical direction is less than a second thickness of the upper substrate in the vertical direction.

3. The semiconductor package of claim 2, further comprising a passive element disposed below the upper substrate and electrically connected to the upper interconnection layer,
wherein a side surface of the passive element is covered by the auxiliary molded layer.

4. The semiconductor package of claim 2, further comprising:
a first connection pattern between the lower substrate and the first semiconductor chip; and
a first underfill material layer extending beyond a side surface of the first semiconductor chip,
wherein the first underfill material layer is covered by the molded portion.

5. The semiconductor package of claim 1,
wherein the upper surface of the lower substrate further includes a third region surrounding the second region, and
wherein the upper substrate overlaps the first region and the second region in the vertical direction and does not overlap the third region in the vertical direction.

6. The semiconductor package of claim 5, wherein the molded portion is disposed on the upper surface of the lower substrate over the first, second, and third regions,
a lower surface of the molded portion is in contact with the lower substrate, an upper surface of the molded portion opposes the lower surface of the molded portion, and an outer side surface of the molded portion connects the lower surface of the molded portion and the upper surface of the molded portion, and
the auxiliary molded layer is disposed on a portion of the upper surface of the molded portion and is disposed over the third region of the lower substrate.

7. The semiconductor package of claim 1, wherein a width of the upper substrate in the first direction is greater than a width of the lower substrate in the first direction.

8. The semiconductor package of claim 7,
wherein the upper substrate includes a non-overlapping region that does not overlap the lower substrate in the vertical direction, and
wherein the auxiliary molded layer is disposed at a portion of the non-overlapping region.

9. The semiconductor package of claim 1, further comprising a fourth semiconductor chip disposed on the lower substrate and spaced apart from the first semiconductor chip in a second direction, intersecting the first direction and the vertical direction,
wherein the fourth semiconductor chip does not overlap the third semiconductor chip in the vertical direction.

10. The semiconductor package of claim 1,
wherein the second semiconductor chip overlaps at least a portion of the first semiconductor chip in the vertical direction, and
wherein the third semiconductor chip overlaps the connection structures in the vertical direction.

11. The semiconductor package of claim 10,
wherein the first semiconductor chip includes a communication processor (CP) chip,
wherein the second semiconductor chip includes a memory chip, and
wherein the third semiconductor chip includes an application processor (AP) chip.

12. The semiconductor package of claim 11, further comprising:
a second connection pattern between the upper substrate and the second semiconductor chip;
a third connection pattern between the upper substrate and the third semiconductor chip; and
a second underfill material layer extending beyond a side surface of the third semiconductor chip.

13. A semiconductor package comprising:
a first semiconductor package including a lower substrate and a first semiconductor chip on the lower substrate;
a second semiconductor package disposed above the first semiconductor package while being spaced apart from the first semiconductor package in a vertical direction and including an upper substrate, a second semiconductor chip on the upper substrate, and a third semiconductor chip spaced apart from the second semiconductor chip in a first direction, intersecting the vertical direction;
connection structures disposed between the first semiconductor package and the second semiconductor package and electrically connecting the first semiconductor package to the second semiconductor package;
a molded portion covering an upper surface of the first semiconductor package, a footprint of the first semiconductor package being different than a footprint of the upper substrate with respect to a plan view; and
an auxiliary molded layer filled between the molded portion and the second semiconductor package.

14. The semiconductor package of claim 13, wherein the molded portion covers an upper surface of the lower substrate and side and upper surfaces of the first semiconductor chip.

15. The semiconductor package of claim 13,
wherein the lower substrate has a first footprint when viewed in the vertical direction, and
wherein the upper substrate has a second footprint when viewed in the vertical direction that is larger than the first footprint.

16. The semiconductor package of claim 13,
wherein the second semiconductor chip overlaps at least a portion of the first semiconductor chip in the vertical direction,
wherein the third semiconductor chip overlaps the connection structures in the vertical direction,
wherein a width of the first semiconductor chip in the first direction that intersects the vertical direction is less than a width of the second semiconductor chip in the first direction, and
wherein the width of the second semiconductor chip in the first direction is less than a width of the third semiconductor chip in the first direction.

17. The semiconductor package of claim 13,
wherein the first semiconductor package has a first width in the first direction different than a second width of the second semiconductor package in the first direction.

18. A semiconductor package comprising:
a lower substrate including a lower interconnection layer and having a first footprint when viewed in a plan view;
a first semiconductor chip disposed on the lower substrate and electrically connected to the lower interconnection layer;
an upper substrate disposed above and spaced apart from the first semiconductor chip in a vertical direction, the upper substrate including an upper interconnection layer and having a second footprint different from the first footprint when viewed in the plan view;
connection structures disposed between the lower substrate and the upper substrate and electrically connecting the lower substrate to the upper substrate;
a second semiconductor chip disposed on the upper substrate and electrically connected to the upper interconnection layer;
a third semiconductor chip on the upper substrate, spaced apart from the second semiconductor chip in a first direction, intersecting the vertical direction, and electrically connected to the upper interconnection layer;
a molded portion covering the first semiconductor chip and disposed on the lower substrate, and the molded portion having a third footprint different than the second footprint with respect to a plan view; and
an auxiliary molded layer filled between the molded portion and the upper substrate.

19. The semiconductor package of claim 18, wherein the second footprint is wider than the first footprint.

20. The semiconductor package of claim 18, wherein the first footprint is wider than the second footprint.
